(19) United States
(12) Patent Application Publication
(10) Pub. No.: US 2008/0203560 A1
(43) Pub. Date: Aug. 28, 2008

(54) Semiconductor device

(75) Inventor: Toshihisa Suzuki, Hamamatsu-shi (JP)

Correspondence Address: PILLSBURY WINTHROP SHAW PITTMAN LLP, P.O BOX 10500, McLean, VA, 22102, US

(73) Assignee: Yamaha Corporation, Hamamatsu-shi (JP)

(21) Appl. No.: 12/011,871

(22) Filed: Jan. 30, 2008

(30) Foreign Application Priority Data
Jan. 31, 2007 (JP) 2007-020979

(51) Int. Cl. H01L 23/34

(52) U.S. Cl. 257/723; 257/E23.08

(57) ABSTRACT

A semiconductor device is produced using a housing having a hollow cavity for embracing a semiconductor sensor chip (e.g., a microphone chip) for detecting pressure variations and an LSI chip for driving the semiconductor sensor chip, both of which are mounted on a chip mount surface. An opening allowing the cavity to communicate with external space is formed at a prescribed position of the chip mount surface within the housing, wherein the LSI chip is positioned above the opening so as to cover at least a part of the opening of the housing. Thus, it is possible to reduce negative influences of environmental factors applied to the semiconductor sensor chip without using an environmental barrier, and it is possible to downsize the semiconductor device.

### BACKGROUND OF THE INVENTION

1. Field of the Invention

The present invention relates to semiconductor devices incorporating semiconductor chips such as microphone chips and pressure sensor chips.

This application claims priority on Japanese Patent Application No. 2007-20979, the content of which is incorporated herein by reference.

2. Description of the Related Art

Conventionally-known portable electronic devices such as portable telephones (or cellular phones) are equipped with semiconductor devices such as microphone modules that detect pressure variations such as sound pressure variations. U.S. Patent Application Publication No. 2006/0116180 discloses an acoustic transducer module including a silicon condenser microphone. In this type of semiconductor device, a semiconductor sensor chip (e.g., a microphone chip) for detecting pressure variations and an amplifier for amplifying the output signal of the semiconductor sensor chip are arranged inside of a housing having a hollow cavity, wherein the housing has an opening allowing the cavity to communicate with external space. Some semiconductor devices are designed such that the opening of the housing is positioned opposite to the semiconductor sensor chip and amplifier both arranged on the surface of a substrate, for example.

A typical example of the semiconductor device in which the opening of the housing is positioned opposite to the surface of the substrate forming the semiconductor sensor chip is designed such that a diaphragm of the semiconductor sensor chip for detecting pressure variations is positioned directly opposite to the opening of the housing. Due to such a structure, it is possible to reduce the overall area of the surface of the substrate, thus reducing the size of the semiconductor device.

In the semiconductor device in which the semiconductor sensor chip is positioned opposite to the opening of the housing, a diaphragm, which is a constituent element of the semiconductor sensor chip, is exposed to external space and is therefore easily influenced by environmental factors such as electromagnetic noise, sunlight, water droplets, and dust.

Some conventionally-known semiconductor devices are equipped with environmental barriers (or protective barriers) for blocking environmental factors from badly affecting semiconductor sensor chips so as to protect semiconductor sensor chips from environmental factors. However, it is troublesome to produce semiconductor devices equipped with environmental barriers.

### SUMMARY OF THE INVENTION

It is an object of the present invention to provide a semiconductor device, which can reduce negative influences due to environmental factors applied to a semiconductor sensor chip without using an independent member serving as an environmental barrier.

It is another object of the present invention to reduce the size of the semiconductor device.

A semiconductor device of the present invention includes a semiconductor sensor chip for detecting pressure variations, a semiconductor chip for driving the semiconductor sensor chip, a housing having a hollow cavity embracing the semiconductor sensor chip and the semiconductor chip, wherein an opening is formed at a prescribed position of a chip mount surface for mounting the semiconductor sensor chip and the semiconductor chip, and wherein the semiconductor chip is arranged above the opening so as to partially cover the opening. This makes it possible to reduce the overall area of the chip mount surface (corresponding to the bottom of the housing) for mounting the semiconductor sensor chip and the semiconductor chip, thus reducing the size of the semiconductor device. Since constituent elements of the semiconductor sensor chip such as a diaphragm is not directly exposed to external space via the opening of the housing, it is possible to reduce negative influences such as electromagnetic noise, sunlight, water droplets, and dust with respect to the semiconductor sensor chip without using an independent member such as an environmental barrier, which is conventionally used.

Since the opening of the housing is partially covered with the semiconductor chip, it is possible to block electromagnetic noise from entering into the opening of the housing by means of the semiconductor chip. That is, it is possible to reliably prevent electromagnetic noise from reaching the semiconductor sensor chip by way of the opening and the cavity; hence, it is possible to reduce noise in the output of the semiconductor device.

In the above, a step portion projects upwardly from the chip mount surface so as to mount the semiconductor chip thereon, so that the step portion forms a part of the chip mount surface. Even when the semiconductor chip is positioned above the opening of the housing so as to entirely cover the opening of the housing, a gap is formed between the semiconductor chip and the chip mount surface for mounting the semiconductor sensor chip by means of the step portion. This allows the opening of the housing to communicate with the cavity via the gap, which realizes a further reduction of the size of the semiconductor device.

In addition, the step portion is formed to cover at least a part of the opening with a gap therebetween. This increases a mounting area for mounting the semiconductor chip; hence, it is possible to mount the semiconductor chip inside of the housing in a stable manner.

Furthermore, the housing is constituted of a substrate having a rectangular shape and a cover member having a recess, by which when the substrate is covered with the cover member, the recess defines the cavity, wherein a sound hole is formed at a prescribed position of the substrate so as to run through the substrate in its thickness direction, thus forming the opening communicating with the cavity. Herein, the sound hole can be formed in a meandering shape running through the substrate. That is, the sound hole is not necessarily formed to linearly run through the substrate in its thickness direction, wherein the sound hole can include a bent portion inside of the substrate and a horizontally extended portion extended in parallel with the chip mount surface within the substrate. Due to such a meandering shape of the sound hole, it is possible to further reduce negative influences of environmental factors with respect to the semiconductor sensor chip.

### BRIEF DESCRIPTION OF THE DRAWINGS

These and other objects, aspects, and embodiments of the present invention will be described in more detail with reference to the following drawings, in which:

FIG. 1 is a longitudinal sectional view showing the constitution of a semiconductor device in accordance with a preferred embodiment of the present invention;

FIG. 2 is a longitudinal sectional view showing the constitution of a semiconductor device in accordance with a variation of the embodiment;

FIG. 3 is a longitudinal sectional view showing the constitution of a semiconductor device in accordance with another variation of the embodiment;

FIG. 4 is a longitudinal sectional view showing the constitution of a semiconductor device in accordance with another variation of the embodiment; and

FIG. 5 is a longitudinal sectional view showing the constitution of a semiconductor device in accordance with another variation of the embodiment.

### DESCRIPTION OF THE PREFERRED EMBODIMENT

The present invention will be described in further detail by way of examples with reference to the accompanying drawings.

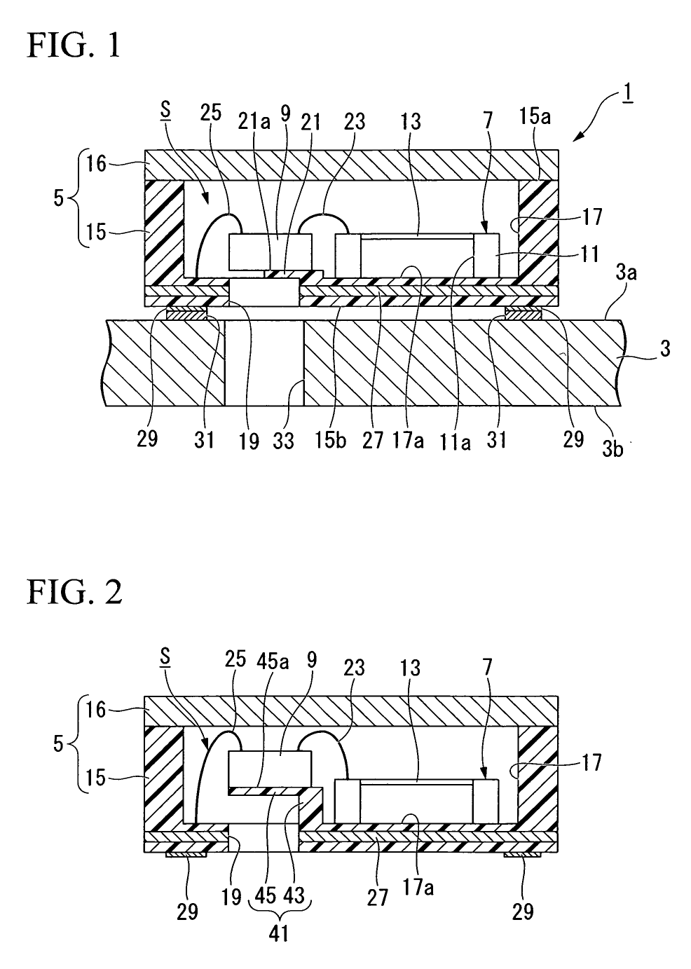

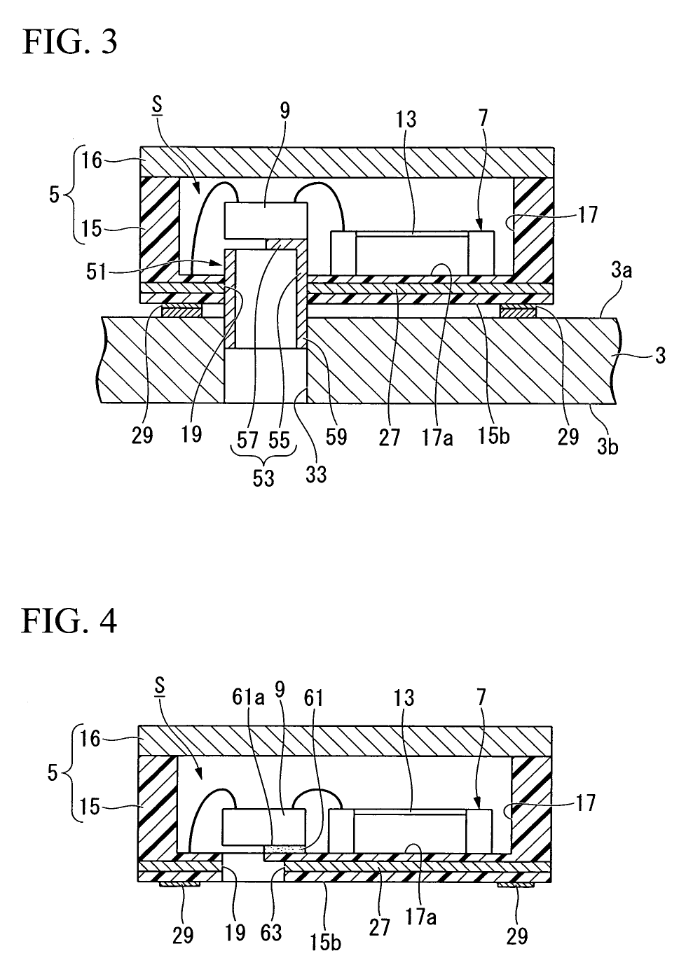

A semiconductor device 1 according to a preferred embodiment of the present invention will be described with reference to FIG. 1. The semiconductor device 1 of FIG. 1 serving as a microphone module for detecting sound is installed in a housing of a portable electronic device such as a portable telephone.

The semiconductor device 1 is mounted on a surface 3a of a circuit board (or a substrate) 3 incorporated in a portable electronic device (not shown), wherein it is constituted of a microphone chip (or a semiconductor sensor chip) 7 and an LSI chip (or a semiconductor chip) 9, which are arranged inside of a hollow cavity S of a housing 5.

The microphone chip 7 includes a diaphragm 13 that covers an inner hole 11a of a support 11. The diaphragm 13 detects pressure variations such as sound pressure variations by way of vibration applied thereto. Hence, the microphone chip 7 forms a sound pressure sensor that converts vibration into electric signals.

The LSI chip 9 drives and controls the microphone chip 7 and is constituted of an amplifier for amplifying electric signals output from the microphone chip 7, an A/D converter for converting electric signals into digital signals, and a digital signal processor (DSP), for example.

The housing 5 includes a substrate 15 and a cover member 16, wherein the cover member 16 is arranged on a surface 15a of the substrate 15 so as to define a cavity S. The substrate 15 is formed using a thick plate having a rectangular shape in plan view so as to form a multilayered wiring substrate. Herein, a recess 17 is recessed from the surface 15a of the substrate 15 so as to define the cavity S.

The microphone chip 17 is mounted on a bottom 17a of the recess 17 via a die-bonding material (not shown) in such a way that the diaphragm 13 is positioned opposite to the bottom 17a through the inner hole 11a.

A sound hole (or a through-hole having an opening) 19 runs through the substrate 15 in its thickness direction so that the cavity S communicates with the external space therethrough. The sound hole 19 is opened at a prescribed position of the bottom 17a of the recess 17. A step portion 21, which slightly projects upwardly from the bottom 17a of the recess 17 towards the cover member 16, is formed in the periphery of the sound hole 19. Along with the bottom 17a of the recess 17, the step portion 21 having a plate-like shape is extended horizontally so as to cover a prescribed area of the sound hole 19.

The LSI chip 9 is mounted on a surface 21a of the step portion 21 via the foregoing die-bonding material. Herein, the LSI chip 9 is partially extended from the edge of the surface 21a of the step portion 21, so that the extended portion of the LSI chip 9 is arranged above the other area (other than the prescribed area) of the sound hole 19, which is not covered with the step portion 21.

In the above, a gap substantially corresponding to the thickness of the step portion 21 is formed between the LSI chip 9 and the bottom 17a of the recess 17; hence, the cavity S of the housing 5 communicates with the external space by way of the gap and the sound hole 19.

The microphone chip 7 and the LSI chip 9, which are positioned relative to the bottom 17a of the recess 17, are electrically connected via a first wire 23. In addition, the LSI chip 9 is electrically connected to an electrode pad (not shown), which is exposed to the bottom 17a of the recess 17, via a second wire 25.

A lower shield layer 27 having conductive property is embedded inside of the substrate 15 so as to cover the overall area of the bottom 17a of the recess 17 except for the opening area of the sound hole 19. A plurality of external connection terminals 29, which are electrically connected to the circuit board 3, are formed on a backside 15b of the substrate 15. The external connection terminals 29 are electrically connected to the aforementioned electrode pads and the lower shield layer 27 via wirings (not shown) formed inside of the substrate 15.

The aforementioned structure allows the microphone chip 7, the LSI chip 9, and the lower shield layer 27 to connected to the circuit board 3. The lower shield layer 27 is connected to a ground pattern (not shown) formed on the circuit board 3. That is, the lower shield layer 27 serves as an electromagnetic shield for blocking electromagnetic noise from entering into the cavity S from the bottom 17a of the recess 17 except for the opening area of the sound hole 19 when the semiconductor device 1 is mounted on the circuit board 3.

The cover member 16 having a rectangular shape is fixed to the surface 15a of the substrate 15 so as to entirely cover the opening of the recess 17, thus forming the cavity S embracing the microphone chip 7 and the LSI chip 9.

The cover member 16 can be formed using a conductive material such as a copper material; alternatively, it can be formed using a non-conductive material having a rectangular shape, on which surface in film composed of a conductive material is formed. The cover member 16 is electrically connected to the lower shield layer 27 of the substrate 15 and the external connection terminals 29 connected to the lower shield layer 27; hence, similar to the lower shield layer 27, the cover member 16 serves as an electromagnetic shield for blocking electromagnetic noise from entering into the cavity S from the upper opening of the recess 17.

A plurality of connection pads 31, which join the external connection terminals 29 via solder, are formed on the surface 3a of the circuit board 3 on which the semiconductor device 1 is mounted. At least one of the connection pads 31 connected to the cover member 16 and the lower shield layer 27 is connected to the ground pattern. A through-hole 33 is formed to run through the circuit board 3 in its thickness direction. When the semiconductor device 1 is mounted on the surface 3a of the circuit board 3, the sound hole 19 of the housing 5 is positioned opposite to the through-hole 33. When sound propagates towards the semiconductor device 1 (mounted on the circuit board 3) from the backside 3b of the circuit board 3 via the through-hole 33, it is transmitted into the cavity S by way of the sound hole 19 of the substrate 15 and the gap between the bottom 17a of the substrate 15 and the LSI chip 9, wherein it may reach the diaphragm 13 of the microphone chip 7 via the upper side of the LSI chip 9, for example.

The semiconductor device 1 is designed such that the LSI chip 9 is arranged above the sound hole 19 so as to cover the sound hole 19 with a gap therebetween. This makes it possible to reduce the overall area of the bottom 17a of the recess 17 for mounting the microphone chip 7 and the LSI chip 9, thus reducing the size of the semiconductor device 1.

Particularly, the semiconductor device 1 of the present embodiment is designed such that the LSI chip 9 is mounted on the surface 21a of the step portion 21 so as to form a gap between the LSI chip 9 and the bottom 17a of the recess 17; therefore, even though the LSI chip 9 is arranged to entirely cover the sound hole 19 with a gap therebetween, it is possible to remarkably reduce the size of the semiconductor device 1 while allowing the cavity S to communicate with external space.

In the aforementioned structure constituent elements such as the diaphragm 13 of the microphone chip 7 are not directly exposed to external space via the sound hole 19. Thus, it is possible to reduce negative influences due to environmental factors such as electromagnetic noise, sunlight, water droplets, and dust with respect to the microphone chip 7 without using an independent member serving as an environmental barrier, which the conventionally-known technology needs.

Since the LSI chip 9 is arranged above the sound hole 19, it is possible to block electromagnetic noise from entering into the cavity S via the sound hole 19 so as to reach the microphone chip 7. That is, the semiconductor device 1 is capable of reliably preventing electromagnetic noise from reaching the microphone chip 7 by means of the LSI chip 9, the cover member 16, and the lower shield layer 27. This realizes a remarkable reduction of noise output from the semiconductor device 1.

Since the step portion 21 is arranged to partially cover the sound hole 19, it is possible to increase the mount area for mounting the LSI chip 9 positioned above the sound hole 19. This makes it possible to arrange the LSI chip 9 in a stable manner.

The present embodiment is not necessarily limited to the aforementioned structure adapted to the semiconductor device 1, which can be further modified in a variety of ways. Variations of the present embodiment will be described below.

In the present embodiment, the step portion 21 is formed in a rectangular plate-like shape; but this is not a restriction. As shown in FIG. 2, it is possible to arrange an L-shaped step portion 41 constituted of a vertical portion 43, which vertically stands from the bottom 17a of the recess 17 in the periphery of the sound hole 19, and a horizontal portion 45, which is horizontally elongated from the upper end of the vertical portion 43 along the bottom 17a of the recess 17 so as to cover the opening of the sound hole 19 with a gap therebetween. Herein, the LSI chip 9 is mounted on a surface 45a of the horizontal portion 45 of the L-shaped step portion 41.

The semiconductor device of FIG. 2 is designed to form a gap between the horizontal portion 45 for mounting the LSI chip 9 and the bottom 17a of the recess 17 by means of the vertical portion 43 of the L-shaped step portion 41. For this reason, the horizontal portion 45 can be further elongated to entirely cover the opening of the sound hole 19 with a gap therebetween. This allows the cavity S to communicate with external space via the gap and the sound hole 19.

The aforementioned step portions 21 and 41 are each formed integrally with the substrate 15; but this is not a restriction. That is, the step portion can be constituted of another member independently of the substrate 15. For example, it is possible to introduce an independent step portion 53 that is constituted of a cylinder 51 engaged with the sound hole 19 of the substrate 15. Specifically, the step portion 53 is constituted of a vertical portion 55, which is a part of a vertical wall of the cylinder 51 partially projecting upwardly from the bottom 17a of the recess 17, and a horizontal portion 57, which is elongated horizontally from the upper end of the vertical portion 55 in a radial direction of the cylinder 51 and is integrally formed together with the cylinder 51.

In addition, the cylinder 51 partially projects downwardly from the backside 15b of the substrate 15 so as to form a projected portion 59 serving as a anti-sound-leak gasket. The projected portion 59 of the cylinder 51 is engaged with the through-hole 33 of the circuit board 3, allowing the cavity S to directly communicate with the through-hole 33 of the circuit board 3 via the cylinder 51. In this structure, sound propagating into the through-hole 33 from the backside 3b of the circuit board 3 does not diffuse in the space between the surface 3a of the circuit board 3 and the backside 15b of the substrate 15 due to the projected portion 59 of the cylinder 51. This makes it possible to efficiently introduce sound into the cavity S.

The semiconductor device 1 of the present embodiment is designed such that that step portion 21 is extended from the periphery of the sound hole 19 so as to partially cover the sound hole 19 with a gap therebetween; but this is not a restriction. It is simply required that at least a part of the LSI chip 9 is arranged above the sound hole 19. That is, it is possible to introduce a step portion 61 shown in FIG. 4, which does not substantially cover the sound hole 19 but is formed in the periphery of the sound hole 19. Herein, a prescribed portion of the LSI chip 9 is mounted on a surface 61a of the step portion 61 positioned in the periphery of the sound hole 19 so that the other portion of the LSI chip 9 partially covers the sound hole 19 with a gap therebetween.

The step portion 61 can be formed integrally with the substrate 15. Alternatively, it can be constituted of another member such as a die-attach material having a prescribed thickness, which serves as a die-bonding material for fixing the LSI chip 9 onto the bottom 17a of the recess 17. In addition, it is possible to form a cutout 63 in the backside 15b of the substrate 15 in such a way that the opening area of the sound hole 19 lying in the backside 15b of the substrate 15 becomes larger than the opening area of the sound hole 19 lying in the bottom 17a of the recess 17.

The semiconductor device 1 of the present embodiment is designed such that the LSI chip 9 is mounted on the surface 21a of the step portion 21; but this is not a restriction. That is, the LSI chip 9 can be directly mounted on the bottom 17a of the recess 17 without the intervention of the step portion 21, which is no longer required. In this case, a prescribed portion of the LSI chip 9 is arranged on the bottom 17a of the recess 17 in the periphery of the sound hole 19 so that the other portion of the LSI chip 9 partially covers the sound hole 19.

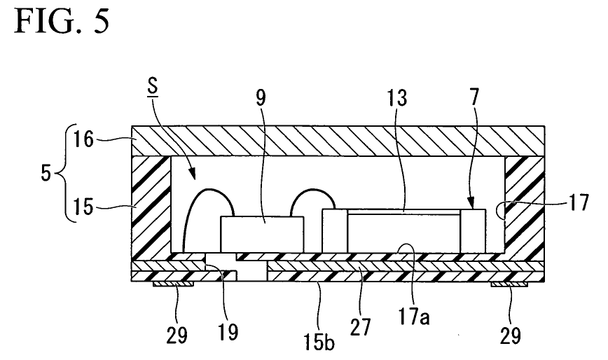

The semiconductor device 1 of the present embodiment is designed such that the sound hole 19 linearly runs through the substrate 15 in its thickness direction from the bottom 17a of the recess 17; but this is not a restriction. It is simply required that the sound hole 19 is formed to run through the substrate 15 in its thickness direction from the bottom 17a of the recess 17 to the backside 15b of the substrate 15. As shown in FIG. 5, the sound hole 19 is formed in a meandering shape running through the substrate 15. This structure is advantageous because it is possible to further reduce negative influences of environmental factors adapted to the microphone chip 7.

The semiconductor device 1 of the present embodiment is designed such that the housing 5 is constituted of the substrate 15 having the recess 17 and the cover member 16 having a rectangular plate-like shape; but this is not a restriction. Alternatively, the housing 5 can be formed in such a way that a substrate having a simple plate-like shape is covered with a cover member having a cylindrical shape whose bottom is positioned opposite to the surface of the substrate for mounting semiconductor chips.

Lastly, the present invention is not necessarily limited to the present embodiment and its variations, which can be further modified in a variety of ways within the scope of the invention defined by appended claims.

1. A semiconductor device comprising:
a semiconductor sensor chip for detecting pressure variations;
a semiconductor chip for driving the semiconductor sensor chip; and
a housing having a hollow cavity embracing the semiconductor sensor chip and the semiconductor chip, wherein an opening is formed at a prescribed position of a chip mount surface for mounting the semiconductor sensor chip and the semiconductor chip,
wherein the semiconductor chip is arranged above the opening so as to partially cover the opening.

2. A semiconductor device according to claim 1, wherein the chip mount surface corresponds to a bottom of the housing.

3. A semiconductor device according to claim 1 further comprising a step portion that projects upwardly from the chip mount surface so as to mount the semiconductor chip thereon, so that the step portion forms a part of the chip mount surface.

4. A semiconductor device according to claim 3, wherein the step portion is formed to cover at least a part of the opening with a gap therebetween.

5. A semiconductor device according to claim 1, wherein the housing includes a substrate having a rectangular shape and a cover member having a recess, by which when the substrate is covered with the cover member, the recess defines the cavity, and wherein a sound hole is formed at a prescribed position of the substrate so as to run through the substrate in its thickness direction, thus forming the opening communicating with the cavity.

6. A semiconductor device according to claim 5, wherein the sound hole is formed in a meandering shape running through the substrate.
